(19) United States
(12) Patent Application Publication
(10) Pub. No.: US 2026/0020219 A1
(43) Pub. Date: Jan. 15, 2026

(54) METHOD FOR MANUFACTURING SEMICONDUCTOR DEVICE USING MULTILAYER MASK

(71) Applicant: NANYA TECHNOLOGY CORPORATION, NEW TAIPEI CITY (TW)

(72) Inventor: CHI-HAO CHAN, NEW TAIPEI CITY (TW)

(21) Appl. No.: 18/805,838

(22) Filed: Aug. 15, 2024

Related U.S. Application Data
(62) Division of application No. 18/769,599, filed on Jul. 11, 2024.

(51) Int. Cl. H10B 12/00

(52) U.S. Cl. CPC H10B 12/0335

(57) ABSTRACT

A method of manufacturing a semiconductor device are provided. The method of manufacturing the semiconductor device includes the steps of: forming an insulating layer on a substrate, forming a multilayer mask on the insulating layer, etching the insulating layer with the multilayer mask, and forming a plurality of lower electrodes in the insulating layer.

### CROSS-REFERENCE TO RELATED APPLICATION

This application is a divisional application of U.S. Non-Provisional application Ser. No. 18/769,599 filed Jul. 11, 2024, which is incorporated herein by reference in its entirety.

### TECHNICAL FIELD

The present disclosure relates to a method for manufacturing a semiconductor device using a multilayer mask.

### DISCUSSION OF THE BACKGROUND

In the manufacturing process of a semiconductor device, such as a dynamic random access memory (DRAM), the formation of contact holes is crucial. This is achieved through an etching operation using a mask. With the rapid advancement of miniaturized semiconductor processing technology, the integration density of semiconductor devices has significantly increased. As a result, the unit cell area has been reduced, and the aspect ratio of the lower electrode of a capacitor has been substantially increased.

However, this increased aspect ratio has led to a common issue: complying with critical dimensions has become challenging, which increases the risk of collapse or breakage of the lower electrode of the capacitor during subsequent operations. To maintain or increase capacitance, addressing the opening of the contact hole is essential. This is a limiting factor that must be resolved to achieve further improvements in semiconductor device integration.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a method of manufacturing a semiconductor device. The method includes forming an insulating layer on a substrate; forming a multilayer mask on the insulating layer; etching the insulating layer with the multilayer mask; and forming a plurality of lower electrodes in the insulating layer.

Another aspect of the present disclosure provides a method of manufacturing a semiconductor device. The method includes forming an insulating layer on a substrate; forming a multilayer mask on the insulating layer; and etching the multilayer mask in at least three etching operations. The multilayer mask includes a first silicon-containing layer, a second silicon-containing layer, and a metal-containing layer disposed between the first silicon-containing layer and the second silicon-containing layer.

Another aspect of the present disclosure provides a method of manufacturing a semiconductor device. The method includes forming an insulating layer on a substrate; forming a multilayer mask on the insulating layer; forming a plurality of contact holes in the multilayer mask; and etching the insulating layer with the multilayer mask. The multilayer mask includes a metal-containing layer configured to prevent the multilayer mask from collapsing.

By utilizing a multilayer mask to define the contact hole, minimal lateral etching is achieved, allowing for more precise critical dimensions. This also reduces the risk of collapse or breakage of the lower electrode of the capacitor during subsequent operations, ultimately leading to improved performance and operational reliability of the semiconductor device.

The foregoing has outlined rather broadly the features and technical advantages of the present disclosure so that the detailed description of the disclosure that follows may be better understood.

Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

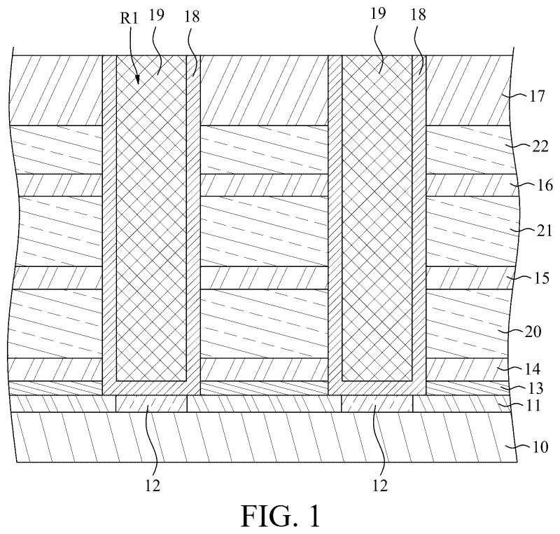

FIG. 1 is a schematic cross-sectional view illustrating the semiconductor device in accordance with some embodiments of the present disclosure.

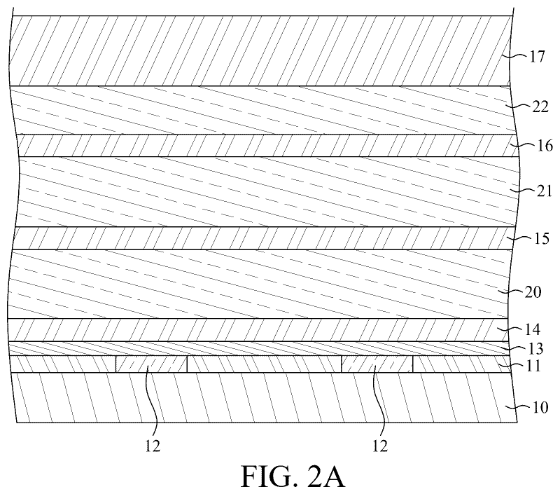

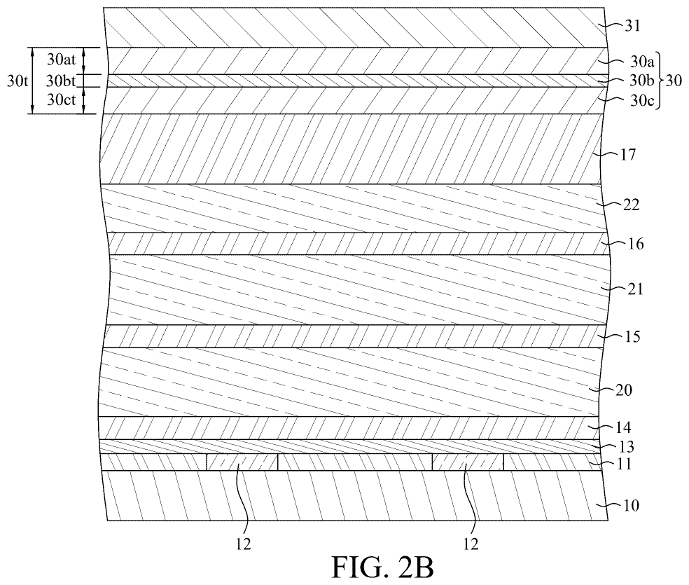

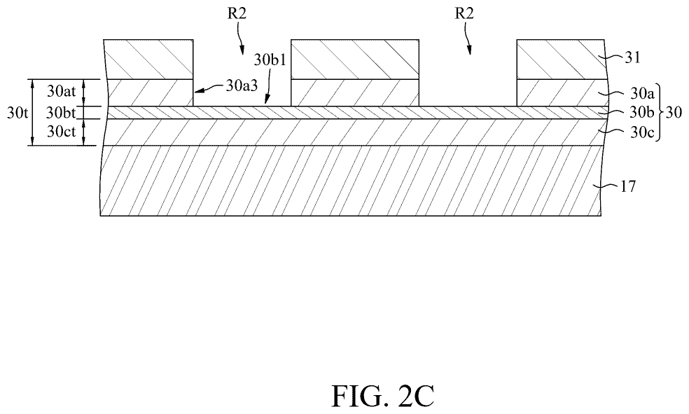

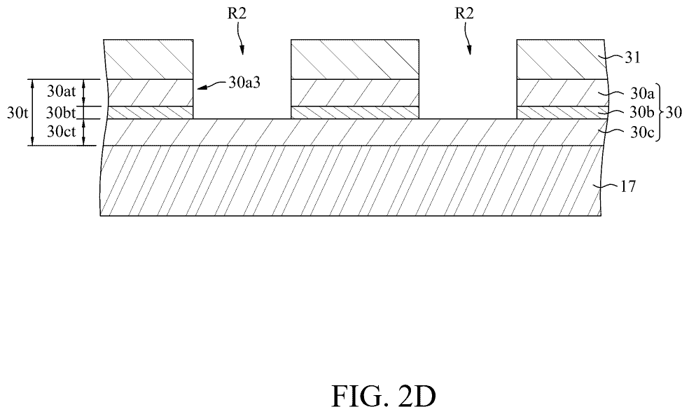

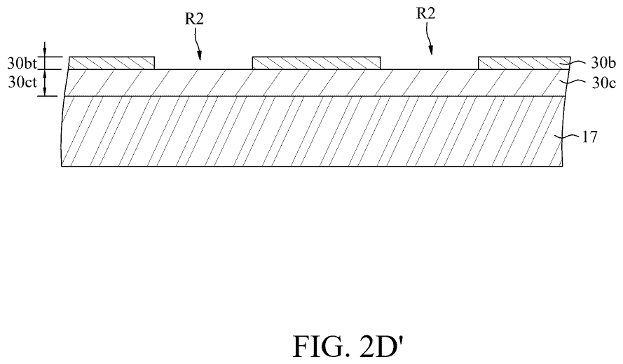

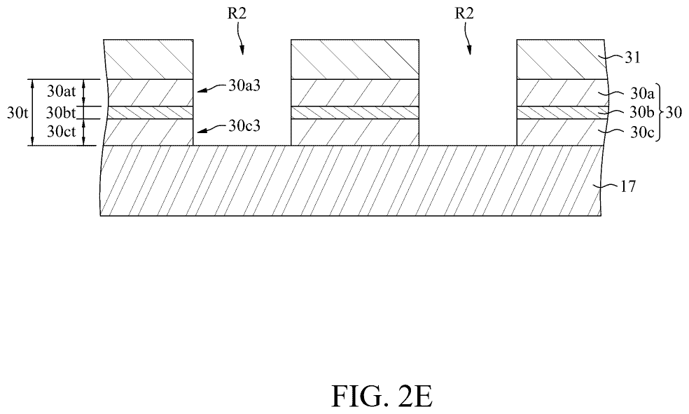

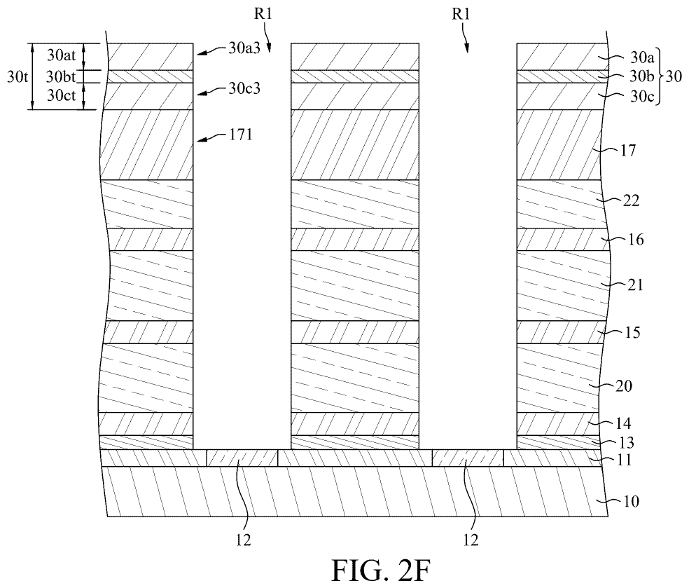

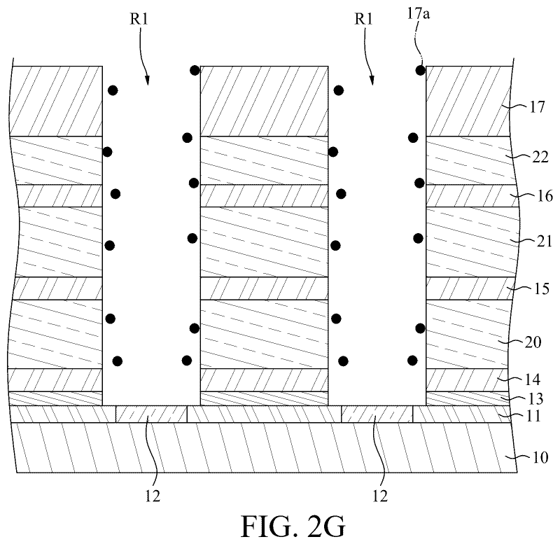

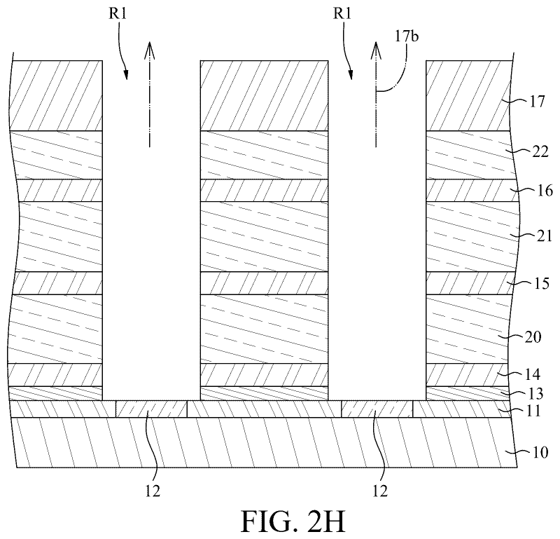

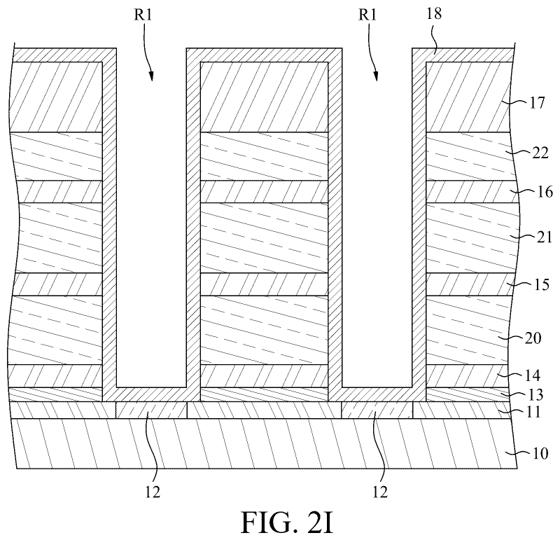

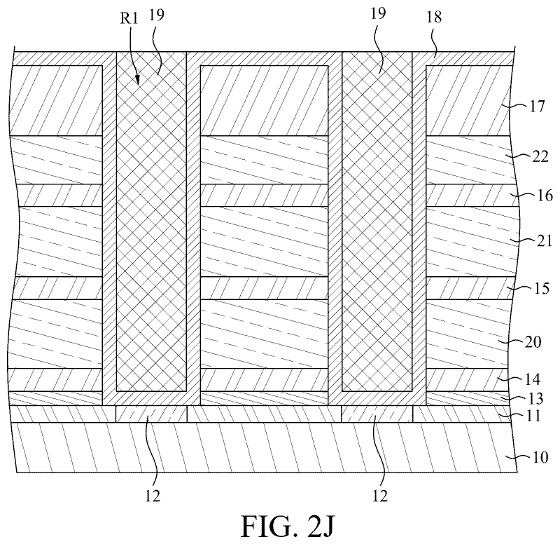

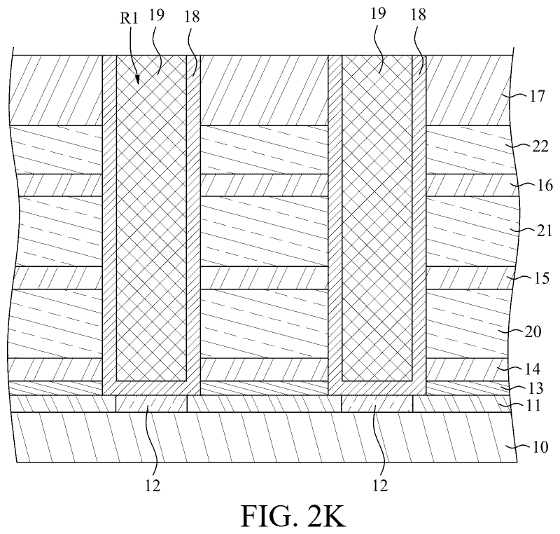

FIG. 2A is a schematic cross-sectional view illustrating one or more stages of a method of manufacturing a semiconductor device in accordance with some embodiments of the present disclosure.

FIG. 2B is a schematic cross-sectional view illustrating one or more stages of a method of manufacturing a semiconductor device in accordance with some embodiments of the present disclosure.

FIG. 2C is a schematic cross-sectional view illustrating one or more stages of a method of manufacturing a semiconductor device in accordance with some embodiments of the present disclosure.

FIG. 2D is a schematic cross-sectional view illustrating one or more stages of a method of manufacturing a semiconductor device in accordance with some embodiments of the present disclosure.

FIG. 2D′ is a schematic cross-sectional view illustrating one or more stages of a method of manufacturing a semiconductor device in accordance with some embodiments of the present disclosure.

FIG. 2E is a schematic cross-sectional view illustrating one or more stages of a method of manufacturing a semiconductor device in accordance with some embodiments of the present disclosure.

FIG. 2F is a schematic cross-sectional view illustrating one or more stages of a method of manufacturing a semiconductor device in accordance with some embodiments of the present disclosure.

FIG. 2G is a schematic cross-sectional view illustrating one or more stages of a method of manufacturing a semiconductor device in accordance with some embodiments of the present disclosure.

FIG. 2H is a schematic cross-sectional view illustrating one or more stages of a method of manufacturing a semiconductor device in accordance with some embodiments of the present disclosure.

FIG. 2I is a schematic cross-sectional view illustrating one or more stages of a method of manufacturing a semiconductor device in accordance with some embodiments of the present disclosure.

FIG. 2J is a schematic cross-sectional view illustrating one or more stages of a method of manufacturing a semiconductor device in accordance with some embodiments of the present disclosure.

FIG. 2K is a schematic cross-sectional view illustrating one or more stages of a method of manufacturing a semiconductor device in accordance with some embodiments of the present disclosure.

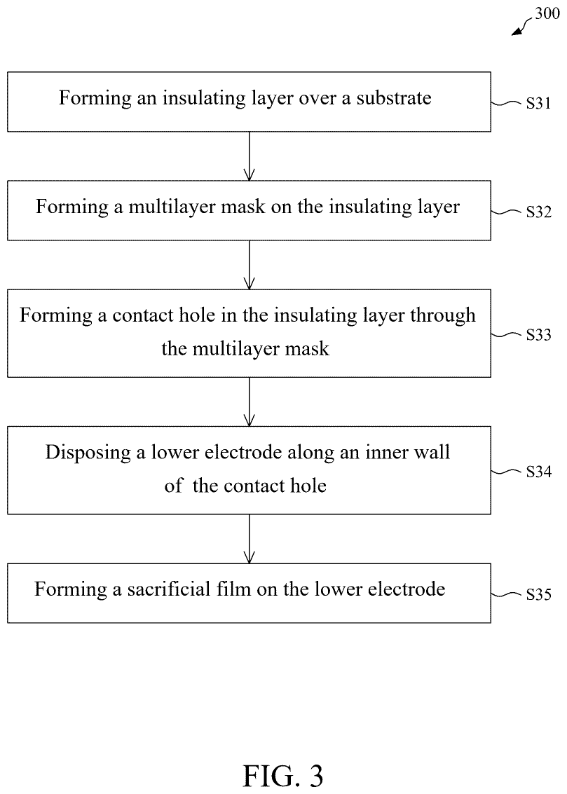

FIG. 3 illustrates a flow chart of a method of manufacturing a semiconductor device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1 is a schematic cross-sectional view illustrating the semiconductor device 1 in accordance with some embodiments of the present disclosure. In some embodiments, the semiconductor device 1 may be disposed adjacent to a circuit. For example, the semiconductor device 1 may be disposed adjacent to a memory device such as a dynamic random access memory (DRAM) device or the like.

The semiconductor device 1 may include a substrate 10, an interlayer insulating layer 11, a plurality of contact plugs 12, an etch stop layer 13, support structure patterns 14, 15, 16, 17, lower electrodes 18, sacrificial films 19, and mold layers 20, 21, 22.

The substrate 10 may include a semiconductor substrate. In some embodiments, the semiconductor material of the substrate 10 may include, for example, silicon (Si) (such as monocrystalline silicon, polysilicon, and amorphous silicon), germanium (Ge), gallium (Ga), and indium (In). In some embodiments, the semiconductor material of the substrate 10 may include a compound semiconductor including silicon germanium (SiGe), silicon carbide (SiC), silicon germanium carbide (SiGeC), gallium arsenide (GaAs), gallium phosphide (GaP), indium arsenide (InAs), indium phosphide (InP), indium antimonide (InSb), or other IV-IV, III-V or II-VI semiconductor materials.

In some embodiments, the substrate 10 may include a bulk semiconductor, a semiconductor-on-insulator (SOI) substrate, a multi-layered substrate, or a gradient substrate. For example, the SOI substrate may include a layer of a semiconductor material formed on an insulator layer. The insulator layer may be, for example, a buried oxide (BOX) layer, a silicon oxide layer, or the like. The insulator layer may be provided on a substrate, typically a silicon or glass substrate. In some embodiments, the substrate 10 may be a wafer, such as a silicon wafer. The substrate 10 may be doped (e.g., with a P-type or an N-type dopant) or undoped.

Although not illustrated, a plurality of the active regions may be defined by an isolation region on the substrate 10. Word lines and bit lines may be formed on the substrate 10.

The interlayer insulating layer 11 may be formed on the substrate 10. The interlayer insulating layer 11 may include silicon oxide (SiO₂), silicon nitride (SiN), or silicon oxynitride (SiON). The interlayer insulating layer 11 may be a single layer or a multi-layer.

The plurality of contact plugs 12 may be formed in the interlayer insulating layer 11 on the substrate 10. The contact plugs 12 may be connected to a source electrode or a drain electrode of a transistor included in the substrate 10. For example, the contact plug 12 may include a landing pad and a storage node contact. The contact plugs 12 may include a conductive material. The contact plugs 12 may include a doped semiconductor material (e.g., doped silicon), a metal (e.g., tungsten, titanium, and tantalum), a conductive metal nitride (e.g., titanium nitride, tantalum nitride, and tungsten nitride), a metal-semiconductor compound (e.g., a metal silicide), or a combination thereof.

The etch stop layer 13 may be disposed on the interlayer insulating layer 11. The etch stop layer 13 may surround a portion of a sidewall of the lower electrode 18. The etch stop layer 13 may include a material having an etch selectivity with respect to the mold layers 20, 21, and 22. The etch stop layer 13 may include silicon nitride (SiN) or silicon oxynitride (SiON).

The support structure patterns 14, 15, 16, and 17 may support the lower electrodes 18. The support structure patterns 14, 15, 16, and 17 may each have a monolithic structure in which an entire portion thereof is connected. The support structure patterns 14, 15, 16, and 17 may each have a flat shape that is parallel to the main surface of the substrate 10 at a certain height from the main surface of the substrate 10. The support structure patterns 14, 15, 16, and 17 may include or define a plurality of contact holes R1.

The support structure patterns 14, 15, 16, and 17 may each include silicon oxycarbide (SiOC), silicon oxynitride (SiON), silicon nitride (SiN), silicon carbon nitride (SiCN), tantalum oxide (TaO), or the like. Although three support structure patterns are illustrated, the inventive concept is not limited thereto. The number of support structure patterns may be two, three, five, or more. The support structure patterns 14, 15, 16, and 17 may be referred to as a first support structure pattern, a second support structure pattern, a third support structure pattern, and a fourth support structure pattern.

The lower electrodes 18 may be formed on the substrate 10. For example, the lower electrodes 18 may be formed on the contact plug 12 formed in the interlayer insulating layer 11. The lower electrodes 18 may be electrically connected with the contact plug 12. The lower electrodes 18 may be formed as extending in a perpendicular direction with respect to the substrate 10.

The lower electrodes 18 may be disposed conformally along a sidewall and a bottom surface of the contact holes R1. The lower electrodes 18 may each have a cylinder shape, e.g., with a U-Shaped cross-section. In comparison with lower electrodes having pillar-type structures, the lower electrodes having cylinder-type structures may have higher capacitance and the heights can be lower. Thus, the probability of the lower electrodes 18 collapsing may be reduced. The lower electrode 18 may include a doped semiconductor material (e.g., doped silicon), a metal (e.g., tungsten, titanium, and tantalum), a conductive metal nitride (e.g., titanium nitride, titanium aluminum nitride, titanium silicon nitride, tantalum nitride, tantalum aluminum nitride, tantalum silicon nitride, and tungsten nitride), a conductive metal oxide (e.g., iridium oxide), or other conductive materials.

The sacrificial film 19 may be formed on the lower electrode 18 to fill the contact hole R1. The sacrificial film 19 may include an oxide such as undoped silica glass (USG), spin on glass (SOG), or the like. The sacrificial film 19 may include a material having excellent gap-filling capability. The sacrificial film 19 may be configured to protect the lower electrode 18 during a polishing process and an etching process.

The mold layers 20, 21, and 22 may each include silicon oxide (SiO₂), undoped silica glass (USG), borosilica glass (BSG), phosphosilica glass (PSG), borophosphosilica glass (BPSG), tetraethyl orthosilicate (TEOS), plasma enhanced tetraethyl orthosilicate (PE-TEOS), and fluoride silicate glass (FSG), etc. The mold layer 20 and the mold layer 21 may be referred to as a first mold layer and a second mold layer. The mold layers 20, 21, and 22 may be referred to as a first mold layer, a second mold layer, and a third mold layer.

As the aspect ratio of the open region R1 increases, the opening shape is difficult to control, potentially increasing the risk of collapse or breakage of the lower electrode of the capacitor during subsequent operations.

According to some embodiments of the present disclosure, the open regions R1 of the semiconductor device 1 are defined by a multilayer mask designed to minimize lateral etching. This advanced design allows for the achievement of more precise critical dimensions, enabling subsequent operations, such as the deposition of conductive material for forming a lower electrode, to be carried out smoothly and uniformly. As a result, the capacitance of the semiconductor device la can be increased.

FIGS. 2A, 2B, 2C, 2D, 2D′, 2E, 2F, 2G, 2H, 2I, 2J, and 2K illustrate stages of a method of manufacturing a semiconductor device in accordance with some embodiments of the present disclosure. At least some of these figures have been simplified for a better understanding of the aspects of the present disclosure. In some embodiments, the semiconductor device 1 in FIG. 1 may be manufactured by the operations described below with respect to FIGS. 2A, 2B, 2C, 2D, 2D′, 2E, 2F, 2G, 2H, 2I, 2J, and 2K.

As shown in FIG. 2A, an insulating layer may be formed over a substrate 10. The insulating layer may include the etch stop layer 13, the support structure pattern 14, the mold layer 20, the support structure pattern 15, the mold layer 21, the support structure pattern 16, the mold layer 22, and the support structure pattern 17 stacked over the substrate 10 in sequence. The insulating layer may be formed by any suitable process, such as chemical vapor deposition (CVD) or physical vapor deposition (PVD).

As shown in FIG. 2B, a multilayer mask 30 and a photoresist 31 may be disposed on the insulating layer.

The multilayer mask 30 may include a silicon-containing layer 30a, a metal-containing layer 30b, and a silicon-containing layer 30c. The silicon-containing layer 30a may be referred to as a first silicon-containing layer and the silicon-containing layer 30c may be referred to as a second silicon-containing layer. The metal-containing layer 30b may be disposed between the silicon-containing layer 30a and the silicon-containing layer 30c. The metal-containing layer 30b may contact (such as directly contact) the silicon-containing layer 30a and the silicon-containing layer 30c.

In some embodiments, the silicon-containing layer 30a and the silicon-containing layer 30c may include a silicon-containing material, such as monocrystalline silicon, polysilicon, amorphous silicon, SiC (silicon carbide), SiOC (silicon oxycarbide), SiCN (silicon carbon nitride), SiOCN (silicon oxycarbonitride), SiO₂ (silicon oxide). In some embodiments, the silicon-containing layer 30a and the silicon-containing layer 30c may include the same material. In some embodiments, the silicon-containing layer 30a and the silicon-containing layer 30c may include different materials.

In some embodiments, the metal-containing layer 30b may include tungsten (W), copper (Cu), titanium (Ti), tantalum (Ta), or other conductive materials. In some embodiments, the metal-containing layer 30b may include a monolithic structure, a monolayer, or a single layer.

In some embodiments, the thickness 30t of the multilayer mask 30 may be about 450 nanometers (nm) to 550 nm, such as 500 nm. The thickness 30at of the silicon-containing layer 30a may be about 225 nm to 265 nm, such as 245 nm. The thickness 30ct of the silicon-containing layer 30c may be about 225 nm to 265 nm, such as 245 nm. In some embodiments, the thickness 30at may be substantially equal to the thickness 30ct. The thickness 30bt of the metal-containing layer 30b may be about 2 nm to 12 nm, such as 5 nm, 6 nm, 7 nm, 8 nm, 9 nm, or 10 nm. The thickness 30bt may be less than the thickness 30ct. The thickness 30bt may be less than the thickness 30at. The ratio of the thickness 30bt to the thickness 30t may be about 1:100 to 1:50.

In some embodiments, the multilayer mask 30 and the photoresist 31 may be formed by any suitable process, such as low-pressure chemical vapor deposition (LPCVD), plasma enhanced-chemical vapor deposition (PECVD), atomic layer deposition (ALD), or physical vapor deposition (PVD), thermally grown, or chemically grown.

As shown in FIG. 2C, the layers under the support structure pattern 17 are not shown in FIGS. 2C, 2D, 2D′, and 2E for conciseness. The multilayer mask 30 may be partially etched by using a suitable etching operation, such as a directional or anisotropic dry etching operation. For example, the silicon-containing layer 30a may be partially etched.

After the etching operation, a plurality of contact holes R2 are formed in the silicon-containing layer 30a. A portion of the multilayer mask 30 may be exposed. For example, the metal-containing layer 30b may be exposed.

In contrast to a configuration where the multilayer mask 30 does not include the metal-containing layer 30b, the multilayer mask 30 with the metal-containing layer 30b may undergo at least three etching operations or steps, resulting in a lower aspect ratio. This allows for precise definition of the area and pattern of the contact hole R2 by the photoresist 31. For example, the lateral surface 30a3 of the silicon-containing layer 30a that defines the contact hole R2 can be substantially perpendicular to the surface 30b1 of the metal-containing layer 30b exposed through the contact hole R2.

As shown in FIG. 2D, the metal-containing layer 30b may be partially etched by using a suitable etching operation, such as a directional or anisotropic dry etching operation.

As shown in FIG. 2E, the silicon-containing layer 30c may be partially etched.

In contrast to a configuration without the metal-containing layer 30b, the multilayer mask 30 with the metal-containing layer 30b provides confinement and support, allowing it to maintain a vertical position without leaning. For example, the metal-containing layer 30b is configured to prevent the multilayer mask 30 from collapsing. In some embodiments, the lateral surface 30a3 of the silicon-containing layer 30a may be aligned with the lateral surface 30c3 of the silicon-containing layer 30c, creating a more uniform and stable structure.

As shown in FIG. 2F, the insulating layer may be etched by using the multilayer mask 30 as an etch mask. A plasma etching operation can be performed. After the etching operation, a plurality of contact holes R1 are formed in the insulating layer.

The area and pattern of the contact hole R2 are precisely transferred in the insulating layer. Therefore, the lateral surface 171 of the insulating layer may be aligned with the lateral surface 30c3 of the silicon-containing layer 30c.

In some other embodiments, before the operation in FIG. 2E or before the operation in FIG. 2F, the silicon-containing layer 30a and the photoresist 31 may be removed as shown in FIG. 2D′ to further decrease the aspect ratio of the contact hole R2.

As shown in FIG. 2G, the photoresist 31 and the multilayer mask 30 may be removed.

In some embodiments, a surface treatment may be performed to protect, modify, or smooth the etched surface. In some embodiments, silicon oxide (SiO₂) 17a may be used in the surface treatment.

As shown in FIG. 2H, etch byproduct(s), residues, or contaminants on the etched surface may be removed (or evaporated, or sublimed) 17b.

As shown in FIG. 2I, a plurality of lower electrodes 18 may be disposed in the contact holes R1. For example, the plurality of lower electrodes 18 may be disposed on the upper surface of the contact plugs 12 exposed by the contact holes R1, on the inner surfaces or walls of the contact holes R1, and on the top surface of the insulating layer. The plurality of lower electrodes 18 may be formed by any suitable process, such as chemical vapor deposition (CVD) or physical vapor deposition (PVD).

As shown in FIG. 2J, a sacrificial film 19 may be formed on the lower electrode 18 to fill the contact hole R1. The sacrificial film 19 may include an oxide such as undoped silica glass (USG), spin on glass (SOG), or the like. The sacrificial film 19 may include a material having excellent gap-filling capability. The sacrificial film 19 may be configured to protect the lower electrode 18 during a polishing process and an etching process.

As shown in FIG. 2K, the sacrificial film 19 and the lower electrode 18 are partially removed through a chemical mechanical polishing (CMP) operation and an etch back operation. The support structure pattern 17 may be exposed.

FIG. 3 illustrates a flow chart of a method 300 of manufacturing a semiconductor device in accordance with some embodiments of the present disclosure.

In some embodiments, the method 300 may include a step S31 of forming an insulating layer over a substrate. For example, as shown in FIG. 2A, an insulating layer may be formed over a substrate 10.

In some embodiments, the method 300 may include a step S31 of forming a multilayer mask on the insulating layer. For example, as shown in FIG. 2B, a multilayer mask 30 and a photoresist 31 may be disposed on the insulating layer.

In some embodiments, the method 300 may include a step S33 of forming a contact hole in the insulating layer through the multilayer mask. For example, as shown in FIG. 2F, the insulating layer may be etched by using the multilayer mask 30 as an etch mask.

In some embodiments, the method 300 may include a step S34 of disposing a lower electrode along an inner wall of the contact hole. For example, as shown in FIG. 21, a plurality of lower electrodes 18 may be disposed in the contact holes R1.

In some embodiments, the method 300 may include a step S35 of forming a sacrificial film on the lower electrode. For example, as shown in FIG. 2J, a sacrificial film 19 may be formed on the lower electrode 18 to fill the contact hole R1.

One aspect of the present disclosure provides a method of manufacturing a semiconductor device. The method includes forming an insulating layer on a substrate; forming a multilayer mask on the insulating layer; etching the insulating layer with the multilayer mask; and forming a plurality of lower electrodes in the insulating layer.

Another aspect of the present disclosure provides a method of manufacturing a semiconductor device. The method includes forming an insulating layer on a substrate; forming a multilayer mask on the insulating layer; and etching the multilayer mask in at least three etching operations. The multilayer mask includes a first silicon-containing layer, a second silicon-containing layer, and a metal-containing layer disposed between the first silicon-containing layer and the second silicon-containing layer.

Another aspect of the present disclosure provides a method of manufacturing a semiconductor device. The method includes forming an insulating layer on a substrate; forming a multilayer mask on the insulating layer; forming a plurality of contact holes in the multilayer mask; and etching the insulating layer with the multilayer mask. The multilayer mask includes a metal-containing layer configured to prevent the multilayer mask from collapsing.

By utilizing a multilayer mask to define the contact hole, minimal lateral etching of the materials to be etched is achieved, allowing for more precise critical dimensions. This also reduces the risk of collapsing or breaking of the lower electrode of the capacitor during subsequent operations, ultimately leading to improved performance and operational reliability of the semiconductor device.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method of manufacturing a semiconductor device, comprising:
forming an insulating layer on a substrate;
forming a multilayer mask on the insulating layer, wherein the multilayer mask includes a first silicon-containing layer, a second silicon-containing layer, and a metal-containing layer disposed between the first silicon-containing layer and the second silicon-containing layer; and
etching the multilayer mask in at least three etching operations.

2. The method of claim 1, further comprising:
forming a plurality of contact holes in the first silicon-containing layer.

3. The method of claim 2, further comprising:
removing the first silicon-containing layer; and
after removing the first silicon-containing layer, forming the plurality of contact holes in the second silicon-containing layer.

4. The method of claim 2, further comprising:
forming the plurality of contact holes in the second silicon-containing layer; and
after forming the plurality of contact holes in the second silicon-containing layer, removing the first silicon-containing layer.

5. The method of claim 1, wherein the first silicon-containing layer and the second silicon-containing layer includes polysilicon.

6. The method of claim 1, wherein the metal-containing layer includes tungsten or copper.

7. The method of claim 1, wherein the metal-containing layer includes a monolithic structure.

8. The method of claim 1, further comprising:
etching the insulating layer by using the multilayer mask as an etch mask.

9. The method of claim 8, wherein a lateral surface of the insulating layer is substantially aligned with a lateral surface of the second silicon-containing layer.

10. The method of claim 8, further comprising:
before etching the insulating layer, removing the first silicon-containing layer.

11. The method of claim 8, wherein the metal-containing layer is configured to support the multilayer mask.

12. The method of claim 8, further comprising:
performing a surface treatment; and
forming a plurality of lower electrodes in the insulating layer.
